(19) United States
(12) Patent Application Publication
(10) Pub. No.: US 2026/0297424 A1
(43) Pub. Date: Oct. 1, 2026

(54) LUMINOPHORE, METHOD FOR PRODUCING A LUMINOPHORE, AND RADIATION-EMITTING COMPONENT

(71) Applicant: ams-OSRAM International GmbH, Regensburg (DE)

(72) Inventors: Gina Maya ACHRAINER, Greifenberg (DE); Johanna STRUBE-KNYRIM, Weil (DE); Daniel BICHLER, Augsburg (DE); Mark VORSTHOVE, Augsburg (DE)

(21) Appl. No.: 18/998,133

(22) PCT Filed: Aug. 2, 2023
(86) PCT No.: PCT/EP2023/071407

§ 371 Date: Jan. 24, 2025

(30) Foreign Application Priority Data
Aug. 4, 2022 (DE) 10 2022 119 601.1

(51) Int. Cl. C09K 11/77; H10H 20/851

(52) U.S. Cl. CPC C09K 11/77748; H10H 20/8512; H10H 20/8515

(57) ABSTRACT

A luminophore with the general formula
A₄L₃₋ₓM₁₊ₓN₉₋ₓOₓ:RE is given, where 0≤x≤3,
A is an element or a combination of elements from the group of rare earth elements,
L is an element or a combination of elements from the group of tetravalent elements,
M is an element or a combination of elements from the group of trivalent elements, and
RE is an activator element. A method for producing a luminophore and a radiation-emitting component are further disclosed.

### CROSS-REFERENCE TO RELATED APPLICATIONS

This application is a national phase of PCT/EP2023/071407 filed on Aug. 2, 2023, which claims priority to German Patent Application No. 102022119601.1, which was filed on Aug. 4, 2022, the entire contents of both of which are incorporated herein by reference.

### TECHNICAL FIELD

A luminophore, a method for producing a luminophore and a radiation-emitting component are disclosed.

### BACKGROUND

To date, hardly any commercial luminophores are known that have a broad adjustability of the emission, i.e. that can convert, for example, blue primary radiation into secondary radiation with different wavelength ranges. For the individual spectral ranges, there have therefore been different material systems to date, each of which only allows a certain degree of adjustability of the emission band, i.e. they are only adjustable to a limited extent. For example, representatives of the garnet system (Y,Gd,Tb)₃(Al,Ga)₅O₁₂:Ce³⁺ are usually used for conversion in the green and yellow spectral range, with which dominant wavelengths (λ_{dom}) of 555 nm to 575 nm can be realized. The systems (Ca,Sr,Ba)₂Si₅N₈:Eu²⁺ and (Ca, Sr)AlSiN₃:Eu²⁺ are known, for example, for the red to deep red spectral range. Dominant wavelengths from 580 nm to 610 nm can usually be realized with the system (Ca, Sr, Ba)₂Si₅N₈:Eu²⁺.

### SUMMARY

A luminophore is provided. According to at least one embodiment, the luminophore has the general formula A₄L₃₋ₓ M₁₊ₓN₉₋ₓ Oₓ:RE, where 0≤x≤3. Furthermore, A is an element or a combination of elements from the group of rare earth elements, L is an element or a combination of elements from the group of tetravalent elements, M is an element or a combination of elements from the group of trivalent elements, and RE is an activator element.

A luminophore described herein can convert electromagnetic radiation of a certain wavelength or a certain wavelength range, hereinafter referred to as primary radiation, into electromagnetic radiation of a second wavelength or a second wavelength range, hereinafter referred to as secondary radiation. The conversion of primary radiation into secondary radiation is also referred to as wavelength conversion. In particular, during wavelength conversion, primary radiation is absorbed by a wavelength-converting element containing the luminophore, converted into secondary radiation by electronic processes at atomic and/or molecular level and re-emitted. Primary and secondary radiation thus have at least partially different wavelength ranges from one another, with the secondary radiation according to one embodiment having a more long-wave wavelength range. In particular, pure scattering or pure absorption of electromagnetic radiation is not meant by the term “wavelength conversion”.

In particular, the luminophore can have a crystalline, for example ceramic, host material into which RE is incorporated as an activator element. The luminophore is a ceramic material, for example.

An activator element is understood here and in the following to be an element that changes the electronic structure of the host material in such a way that electromagnetic radiation of the first wavelength range can be absorbed by the luminophore. This primary radiation can excite an electronic transition in the luminophore, which can return to the ground state by emitting electromagnetic radiation of the second wavelength range. The activator element RE, which is introduced into the host material, is thus responsible for the wavelength-converting properties of the luminophore.

Luminophores are described here and in the following using molecular formulae. The elements listed in the molecular formulae are present in charged form. Here and in the following, elements and/or atoms in relation to the molecular formulae of the luminophores therefore refer to ions in the form of cations and anions, even if this is not explicitly stated. This also applies to element symbols if these are given without a charge number for the sake of clarity. In particular, A, L, M and RE are present as cations, while 0 and N are present as anions. RE, for example, has a triple positive charge and can therefore also be specified as RE³⁺.

It is possible that the luminophore comprises further elements, for example in the form of contaminations, in the case of the given molecular formulae. Taken together, these contaminations have a maximum of 5 mol %, in particular a maximum of 1 mol %, preferably a maximum of 0.1 mol %.

The luminophore can be uncharged on the outside. This means that there can be a complete charge balance between positive and negative charges on the outside of the luminophore. On the other hand, it is also possible that the luminophore formally does not have a complete charge balance to a small extent.

Rare earth elements here include the chemical elements of the 3rd subgroup of the periodic table and the lanthanides. Rare earth elements are generally selected from the group formed by scandium, yttrium, lanthanum, cerium, praseodymium, neodymium, promethium, samarium, europium, gadolinium, terbium, dysprosium, holmium, erbium, thulium, ytterbium and lutetium.

The term “valency” in relation to a specific element jere refers to how many elements with a single opposite charge are required in a chemical compound in order to achieve a charge balance. The term “valency” therefore includes the charge number of the element.

Trivalent elements are elements with a valence of three. Trivalent elements often have a triple positive charge in chemical compounds and have a charge number of +3. A charge balance in a chemical compound can take place, for example, via an element that has a triple negative charge or via three elements that have a single negative charge.

Tetravalent elements are elements with a valence of four. Tetravalent elements are often four times positively charged in chemical compounds and have a charge number of +4. A charge balance in a chemical compound can take place, for example, via an element that is four times negatively charged, by two elements that are twice negatively charged, or by four elements that have a single negative charge.

A luminophore described here has an emission position that can be adjusted over a wide wavelength range and can therefore be used and applied in a variety of ways. In particular, the luminophore can emit secondary radiation in the blue-green to red spectral range when excited with primary radiation from the blue or UV (UV: ultraviolet) spectral range. This means that it can be used, for example, in radiation-emitting components such as white light-emitting LEDs (LED: light-emitting diode), in which a semiconductor chip emits blue and/or UV primary radiation, which is partially converted into secondary radiation by the luminophore.

On the other hand, the luminophore described here can also be used for full conversion in LEDs if it completely converts the primary radiation into secondary radiation. If the luminophore emits in the orange spectral range, for example, an LED with full conversion can then be used for flashlights of cars, for example.

If the luminophore emits in the blue-green or yellow-green spectral range, it is also suitable for Human Centric Lighting (HCL) applications where the effects of light on a human are important. As the spectral position of an electromagnetic radiation emitted by the luminophore in the blue-green or green-yellow range has a high overlap with the melanopic curve, it is therefore possible to influence the alertness of the observer in particular.

In addition, the luminophore described here has an extended color temperature (CCT, correlated color temperature) range and improved color rendering index (CRI) values compared to conventional luminophores.

The luminophore described here exhibits adjustability over a broad wavelength range from the blue-green to red spectral range. A controlled shiftability or adjustability of the emission position over such a wide wavelength range with only one luminophore system is advantageous for various applications, as they represent efficient and/or simple and thus convenient solutions for the application. In the luminophore described here, the emission position can be controlled, for example, via the composition and/or the content of activator element. For example, the emission position can be shifted towards red as the content of the activator element RE increases.

According to at least one embodiment, RE is an element or a combination of elements from the group Ce, Eu, Tb, Sm and Pr. In particular, RE is Ce. Ce is then present in the luminophore with a triple positive charge and can also be indicated as Ce³⁺. The use of Ce as an activator element can lead to a luminophore that is particularly stable against quenching.

According to at least one embodiment, L is Si. According to at least one further embodiment, M is Al.

According to at least one embodiment, the luminophore has the general formula La₄Si₃₋ₓAl₁₊ₓN₉₋ₓOₓ:RE with 0<x≤3. Here, Si is used for L and Al for M and La for A. Furthermore, x is selected to be greater than 0 so that 0 is necessarily present. RE can be selected as explained above. For example, RE is Ce.

According to at least one further embodiment, the luminophore has the general formula La₄Si₃₋ₓAl₁₊ₓN₉₋ₓOₓ:Ce. Such a luminophore emits, in particular broadband, in the blue-green to red spectral range and can therefore be used without combination with other luminophores for solutions that require broadband emission in these spectral ranges, for example in warm-white illuminating devices.

According to at least one embodiment, the luminophore comprises a crystalline, for example ceramic, host lattice. The luminophore is, for example, a ceramic material.

In particular, the crystalline host lattice is made up of a three-dimensional unit cell that generally repeats periodically. In other words, the unit cell is the smallest recurring unit of the crystalline host lattice. The elements L, M, N and 0 each occupy fixed positions, so-called point positions, of the three-dimensional unit cell of the host lattice.

Six lattice parameters, three lengths a, b and c and three angles α, β and γ, are required to uniquely describe the three-dimensional unit cell of the crystalline host lattice. The three lattice parameters a, b and c are the lengths of the lattice vectors that span the unit cell. The other three lattice parameters α, β and γ are the angles between these lattice vectors. α is the angle between b and c, β is the angle between a and c and γ is the angle between a and b.

According to at least one embodiment, the luminophore described here crystallizes in a monoclinic space group. In particular, the luminophore crystallizes in the monoclinic space group P2₁/n. This can be determined, for example, by means of single crystal X-ray diffraction. According to at least one embodiment, the luminophore crystallizes in the monoclinic space group P2₁/n and has lattice parameters that have the following ranges: 650 pm≤a≤700 μm, 530 pm≤b≤580 pm, 1250 pm≤c≤1310 μm, 850°≤α≤95°, 950≤β≤115°, 85°≤γ≤95°.

According to at least one embodiment, the luminophore comprises first L-centered L(N,O)₄-tetrahedra, first M-centered M(N,O)₄-tetrahedra, second L-centered L(N,O)₄-tetrahedra and second M-centered M(N,O)₄-tetrahedra. There are thus two crystallographically different types of tetrahedra, the tetrahedra of the first type, i.e. the first M- or L-centered L(N,O)₄-tetrahedra and M(N,O)₄-tetrahedra, and the tetrahedra of the second type, i.e. the second M- or L-centered L(N,O)₄-tetrahedra and M(N,O)₄-tetrahedra. For example, the luminophore has first and second Si-centered Si(N,O)₄-tetrahedra and first and second Al-centered Al(N,O)₄-tetrahedra.

According to at least one embodiment, the tetrahedra each have a tetrahedron gap. The tetrahedron gap is an area inside the respective tetrahedron. For example, the term “tetrahedron gap” refers to the area inside the tetrahedron that remains free when balls are placed in the corners of the tetrahedron that are in contact with each other.

The N and/or O atoms of the tetrahedra span the tetrahedron, with the L or M atom located in the tetrahedron gap of the stretched tetrahedron. The L or M atom is surrounded by four N and/or O atoms in the shape of a tetrahedron. In particular, all the atoms that span the tetrahedron have a similar distance to the L or M atom located in the tetrahedron gap.

According to at least one embodiment, the first L-centered L(N,O)₄-tetrahedra and M-centered M(N,O)₄-tetrahedra are corner-linked on all sides. Corner-linked on all sides means that each tetrahedron is linked via all four corners to one corner of another tetrahedron respectively. According to at least one further embodiment, the second L-centered L(N,O)₄-tetrahedra and M-centered M(N,O)₄-tetrahedra each have a terminal N or O. The tetrahedra of the second type are thus linked via a total of three corners to further tetrahedra. The first and second tetrahedra thus together form a three-dimensional spatial network structure of corner-linked tetrahedra.

According to at least one embodiment, the first L-centered L(N,O)₄-tetrahedra and M-centered M(N,O)₄-tetrahedra are linked to two first L-centered L(N,O)₄-tetrahedra and/or M-centered M(N,O)₄-tetrahedra and to two second L-centered L(N,O)₄-tetrahedra and/or M-centered M(N,O)₄-tetrahedra. In other words, the tetrahedra of the first type are corner-linked on all sides to two further tetrahedra of the first type and to two tetrahedra of the second type.

According to at least one embodiment, the second L-centered L(N,O)₄ tetrahedra and M-centered M(N,O)₄-tetrahedra are linked to two first L-centered L(N,O)₄-tetrahedra and/or M-centered M(N,O)₄-tetrahedra and to one second L-centered L(N,O)₄-tetrahedron or M-centered M(N,O)₄-tetrahedron. In other words, the tetrahedra of the second type are linked via a total of three corners to two tetrahedra of the first type and to one tetrahedron of the second type.

According to at least one embodiment, the first L-centered L(N,O)₄-tetrahedra, first M-centered M(N,O)₄-tetrahedra, second L-centered L(N,O)₄-tetrahedra and second M-centered M(N,O)₄-tetrahedra form four-membered rings. In other words, the tetrahedra of the first type and the tetrahedra of the second type form four-membered rings. These four-membered rings can each contain two tetrahedra of the first type and two tetrahedra of the second type, wherein a tetrahedron of one type is only linked to two tetrahedra of the other type within the four-membered ring. In other words, there may be an alternating sequence of the two types of tetrahedra within the four-membered ring.

According to at least one embodiment, the four-membered rings are connected to other four-membered ring via corners of the tetrahedra. The connection to the next four-membered ring can be made to a tetrahedron of the same type. The tetrahedra of the first type link thus to two further tetrahedra of the first type, each of which is part of two further four-membered rings. The tetrahedra of the second type only link to one further tetrahedron of the second type, which is part of another four-membered ring. The fourth corner of the tetrahedra of the second type has a terminal anion, i.e. N or O.

In the three-dimensional spatial network structure formed by the corner-linked tetrahedra, cavities or channels can arise in which the A atoms, for example La, are arranged. The A atoms are distributed over two crystallographic positions, i.e. symmetrically different positions. In both positions, the A atom can be surrounded by seven anions, i.e. N and/or O, wherein the anions each form distorted, single-capped octahedra.

According to at least one embodiment, the luminophore has an absorption range at least in the UV to blue wavelength range of the electromagnetic spectrum. The luminophore can thus be excited to emit radiation using semiconductor chips that emit blue or UV radiation, for example.

According to at least one embodiment, the luminophore emits in the blue-green to red wavelength range of the electromagnetic spectrum. The luminophore is thus suitable for use as a conversion luminophor, for example in LEDs, in various color ranges and can therefore be used flexibly. For example, a luminophore described here, which emits in the yellow-orange spectral range, can be used well as a single conversion luminophor solution for warm-white LEDs. On the other hand, a luminophore described here that emits in the blue-green spectral range can be used as a blue-green component in HCL applications.

According to at least one embodiment, an electromagnetic radiation emitted by the luminophore has a dominant wavelength (λ_{dom}) between 500 nm and 600 nm inclusive, in particular between 510 nm and 590 nm inclusive. This range is significantly extended compared to conventional luminophores.

To determine the dominant wavelength of the electromagnetic radiation emitted by the luminophore, a straight line is drawn in the CIE standard diagram from the white point through the color location of the electromagnetic radiation.

The intersection of the straight line with the spectral color line delimiting the CIE standard diagram denotes the dominant wavelength of the electromagnetic radiation. In general, the dominant wavelength differs from the wavelength of the emission maximum.

According to at least one embodiment, an electromagnetic radiation emitted by the luminophore has an emission maximum of at least one emission peak between 480 nm and 630 nm inclusive, in particular between 485 nm and 625 nm inclusive.

According to at least one embodiment, an electromagnetic radiation emitted by the luminophore has a spectral half-width between 70 nm and 160 nm inclusive, in particular between 75 and 150 nm inclusive. The luminophore thus emits broadband radiation and can therefore be used without combination with other luminophores for solutions that require broadband emission in certain spectral ranges.

A method for producing a luminophore is further provided. In particular, the method can be used to produce a luminophore as described above. All features and embodiments disclosed in connection with the luminophore thus also apply to the method and vice versa.

According to at least one embodiment, with the method e a luminophore is produced, the luminophore having the general formula A₄L₃₋ₓM₁₊ₓN₉₋ₓOₓ:RE where 0≤x≤3, A is an element or a combination of elements from the group of rare earth elements, L is an element or a combination of elements from the group of tetravalent elements, M is an element or a combination of elements from the group of trivalent elements, and RE is an activator element.

According to at least one embodiment, the method comprises the steps of
provision of reactants,
mixing the reactants to form a reactant mixture, and
heating the reactant mixture.

According to at least one embodiment, the reactants are selected from a group comprising oxides, nitrides, carbonates, nitrates, oxalates, citrates and hydroxides each of A, L, M and RE and combinations thereof. For example, LaN, Si₃N₄, AlN, Al₂O₃ and CeO₂ can be selected as reactants. These reactants can be used, for example, to produce the luminophore with the composition La₄Si₃₋ₓ Al₁₊ₓN₉₋ₓOₓ:Ce³⁺.

According to at least one embodiment, the mixing is carried out in a hand mortar, a mortar mill, a ball mill or a multi-axis mixer. Other devices suitable for mixing the reactants are also conceivable.

According to at least one embodiment, the reactant mixture is transferred to a crucible before heating. The crucible can be made of tungsten, for example.

During heating, the reactant mixture is made to react and the luminophore is formed.

According to at least one embodiment, the reactant mixture is heated to a temperature in the range from 1500° C. to 1900° C. inclusive. For example, the reactant mixture is heated to a temperature of 1700° C.

According to at least one embodiment, the reactant mixture is heated for a period of from 10 hours inclusive up to and including 14 hours. For example, the reactant mixture is heated for 12 hours.

According to at least one embodiment, the reactant mixture is heated in a forming gas atmosphere or N₂ atmosphere. According to one embodiment, the forming gas atmosphere can be composed of N₂ and H₂, for example with a ratio of 95/5.

According to at least one embodiment, the reactant mixture is heated under a pressure of up to 12 bar, in particular under a pressure of 1 bar inclusive up to and including 10 bar.

After heating, the resulting product can be cooled and ground. Grinding can again take place in a hand mortar, a mortar mill or a ball mill.

A radiation-emitting component is further provided. The luminophore described above is particularly suitable and intended for use in a radiation-emitting component. Features and embodiments described in connection with the luminophore and the method for producing a luminophore thus also apply to the radiation-emitting component and vice versa.

According to at least one embodiment, the radiation-emitting component comprises
a semiconductor chip which emits electromagnetic radiation of a first wavelength range during operation, and
a conversion element comprising a luminophore described herein which converts electromagnetic radiation of the first wavelength range into electromagnetic radiation of a second wavelength range which is at least partially different from the first wavelength range.

The electromagnetic radiation of the first wavelength range forms the emission spectrum of the semiconductor chip and is also referred to as primary radiation.

The semiconductor chip is, for example, a light-emitting diode chip or a laser diode chip. The component can therefore be a light-emitting diode (LED) or a laser. Preferably, the semiconductor chip has an epitaxially grown semiconductor layer sequence with an active zone that is suitable for generating electromagnetic radiation. For example, the active zone has for this a pn junction, a double heterostructure, a single quantum well or a multiple quantum well structure.

During operation, the semiconductor chip can emit electromagnetic radiation, for example from the ultraviolet spectral range and/or from the visible spectral range, in particular from the blue spectral range. The primary radiation thus has wavelengths from the range 400 nm to 500 nm, in particular 400 nm to 480 nm, for example.

According to one embodiment, the conversion element is arranged on the semiconductor chip, in particular on a radiation exit surface of the semiconductor chip, for example in the beam path of the semiconductor chip. This means that at least part of the radiation emitted by the semiconductor chip is incident on the conversion element.

The luminophore in the conversion element converts electromagnetic radiation of the first wavelength range into electromagnetic radiation of a second wavelength range. The electromagnetic radiation of the second wavelength range forms the emission spectrum of the luminophore and is also referred to as secondary radiation.

The electromagnetic radiation of the second wavelength range is at least partially different from the first wavelength range. The luminophore contained in the conversion element or of which the conversion element consists of imparts wavelength-converting properties to the conversion element. For example, the conversion element only partially converts the electromagnetic radiation of the semiconductor chip into electromagnetic radiation of the second wavelength range, while a further part of the electromagnetic radiation of the semiconductor chip is transmitted by the conversion element. In this case, the radiation-emitting component emits mixed light, which is composed of electromagnetic radiation of the first wavelength range and electromagnetic radiation of the second wavelength range. The mixed light comprises, for example, white, in particular warm-white, light. If the primary radiation is completely converted by the conversion element and/or there is no transmission of primary radiation by the conversion element, this is referred to as full conversion. In this case, the radiation-emitting component emits the secondary radiation emitted by the conversion element, in particular from the blue-green to red, for example from the yellow-orange range.

Due to the nature of the luminophore described here, the radiation-emitting component can be used for a wide range of applications. The broadband emission of the luminophore in the blue-green to red spectral range allows it to be used solely in the conversion element, for example in warm-white illuminating devices. If the luminophore emits in the yellow-orange-red spectral range, for example, the radiation-emitting component can be used if, in addition to brightness, a slight red component is also required in the emitted radiation, as is the case with lighting solutions for general lighting, car headlights or flashlights, for example. A radiation-emitting component containing the luminophore described here can also be used well for HCL applications if the luminophore emits in the blue-green or green-yellow spectral range, for example, and the radiation emitted by the radiation-emitting component therefore has a high overlap with the melanopic curve.

According to at least one embodiment, the conversion element is free of another luminophore. Due to its nature, the luminophore described here can be used well without combination with other luminophores, for example if broadband emission in blue-green or green-yellow to red spectral ranges is desired.

Alternatively, according to a further embodiment, at least one further luminophore may be present in the conversion element. The at least one further luminophore may, for example, be selected from the group comprising Ce³⁺ doped garnets such as YAG and LuAG, for example (Y,Lu,Gd,Tb)₃(Al₁₋ₓ,Gaₓ)₅O₁₂:Ce³⁺; Eu²⁺ doped nitrides, for example (Ca, Sr)AlSiN₃:Eu²⁺, Sr(Ca, Sr) Si₂Al₂N₆:Eu²⁺ (SCASN), (Ca, Ba, Sr)₂Si₅N₈:Eu²⁺, SrLiAl₃N₄:Eu²⁺, SrLi₂Al₂O₂N₂:Eu²⁺; Ce³⁺ doped nitrides, for example (Ca,Sr)Al_{(1-4x/3)}Si₍₁₊ₓ₎N₃:Ce; (x=0.2-0.5); Eu²⁺ doped sulphides, (Ba, Sr, Ca) Si₂O₂N₂:Eu²⁺, SiAlONs, nitrido-orthosilicates, orthosilicates (Ba,Sr,Ca)₂SiO₄:Eu²⁺; chlorosilicates (e.g. Ca₈Mg(SiO₄)₄Cl₂:Eu²⁺); Mn⁴⁺ doped fluorides, for example (K,Na)₂ (Si, Ti) F₆:Mn⁴⁺; Eu²⁺ or Ce³⁺ doped litho-silicates, such as (Li,Na,K, Rb, Cs) (Li₃SiO₄):E with E as Eu²⁺, Ce³⁺, or (Sr, Li) Li₃AlO₄:Eu²⁺ or SrLi₃AlO₄:Eu²⁺.

According to at least one embodiment, the conversion element is designed as a conversion layer. The conversion layer can be applied in direct or indirect contact with the semiconductor chip, in particular with the radiation exit surface of the semiconductor chip. In the case of indirect contact, it can be applied to the semiconductor chip by means of an adhesive layer, for example, or a potting can be applied between the semiconductor chip and the conversion element.

According to a further embodiment, the semiconductor chip, optionally the conversion layer and optionally an adhesive layer can be surrounded by a potting. For example, the semiconductor chip, conversion element and, optionally, an adhesive layer are all surrounded by a potting. The semiconductor chip, conversion layer and, if applicable, adhesive layer can then be arranged in the depression of a housing, in which the potting is also arranged.

A potting can have a transmittance for the primary radiation and/or the secondary radiation and/or the radiation emitted by other luminophores present that is at least 85%, preferably 95%. Furthermore, a potting can have silicone or epoxy resin as a material, for example.

According to at least one embodiment, the luminophore in the conversion element is present as a ceramic. The conversion layer can consist of the luminophore forming the ceramic.

According to at least one embodiment, the luminophore in the conversion element is embedded in a matrix. In particular, the luminophore is present in particle form embedded in a matrix.

The matrix may, for example, comprise a material selected from a group including polymers and glass. As polymers, for example, polystyrene, polysiloxane, polysilazane, PMMA, polycarbonate, polyacrylate, polytetrafluoroethylene, polyvinyl, silicone resin, silicone, epoxy resin and transparent synthetic rubber may be chosen. Silicates, water glass and quartz glass, for example, can be selected as glass.

### BRIEF DESCRIPTION OF THE DRAWINGS

Further advantageous embodiments and further developments of the luminophore, the method and the component result from the exemplary embodiment described below in conjunction with the figures.

FIG. 1 shows a schematic sectional view of a radiation-emitting component according to an exemplary embodiment.

FIG. 2 shows a schematic sectional view of a radiation-emitting component according to an exemplary embodiment.

FIG. 3 shows a section of the crystal structure of a luminophore according to an exemplary embodiment.

FIG. 4 shows emission spectra of luminophores according to exemplary embodiment.

FIG. 5 shows the emission spectrum of a comparative example.

Elements that are identical, similar or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

### DETAILED DESCRIPTION

The task of at least one embodiment is to provide a luminophore with improved properties. The task of at least one further embodiment is to provide a method for producing a luminophore with improved properties. The task of at least one further embodiment is to provide a radiation-emitting component with improved properties. These tasks are solved by a luminophore, a method and a radiation-emitting component according to the independent claims.

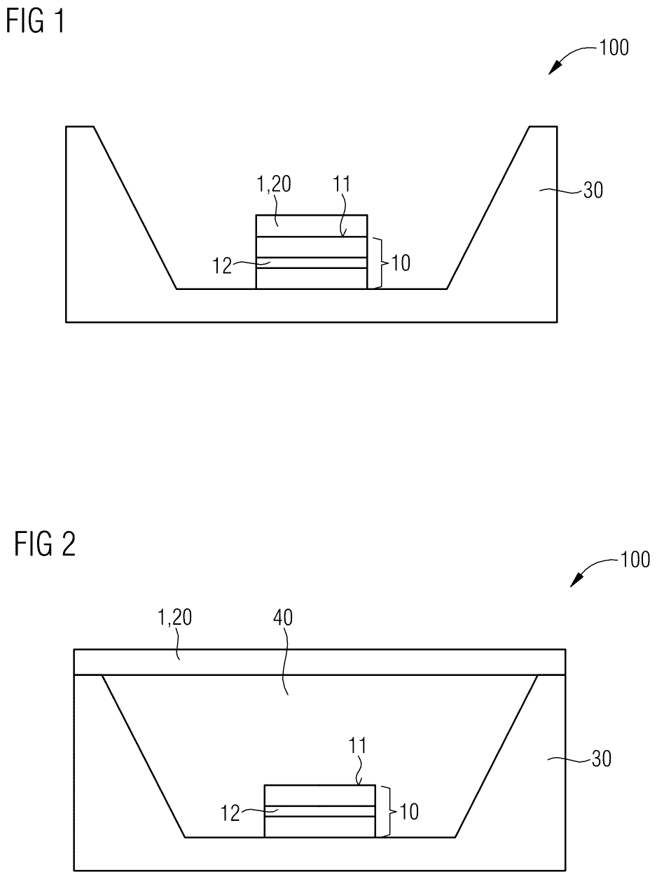

FIG. 1 shows a schematic sectional view of a radiation-emitting component 100 according to an exemplary embodiment. The radiation-emitting component 100 has a semiconductor chip 10. During operation, the semiconductor chip 10 emits electromagnetic radiation of a first wavelength range (primary radiation) from a radiation exit surface 11. The semiconductor chip 10 has an epitaxially grown semiconductor layer sequence with an active zone 12, which is suitable for generating electromagnetic radiation. The primary radiation has wavelengths in the blue and/or UV range.

Furthermore, the component has a conversion element 20. The conversion element 20 either contains a matrix in which the luminophore 1, in particular particles of the luminophore 1, is embedded, or the conversion element 20 has or consists of a ceramic formed from the luminophore 1.

In this exemplary embodiment, the conversion element 20, which is designed here as a conversion layer, is applied directly to the semiconductor chip 10, in particular to its radiation exit surface 11. The conversion element 20 can also be attached to the semiconductor chip 10, for example by means of an adhesive layer (not explicitly shown here).

The semiconductor chip 10 with the conversion element 20 arranged thereon is arranged in the recess of a housing 30. In this exemplary embodiment, the housing 30 has side surfaces that are beveled towards the semiconductor chip 10 that can be reflective. The semiconductor chip 10 and the conversion element 20 may be surrounded by a potting 40 in the housing 30 (not shown here). However, the presence of a potting 40 is not absolutely necessary.

Alternatively, the housing 30 can also have no side walls and thus no recess and be designed as a carrier (not shown here).

FIG. 2 shows a further exemplary embodiment of a radiation-emitting component. For the elements with the same reference signs, the explanations given in relation to FIG. 1 apply unless otherwise stated.

In this exemplary embodiment, the conversion element 20 is not arranged directly on the semiconductor chip 10, but spaced from it on the side of a potting 40 facing away from the semiconductor chip 10, which is arranged in the recess of the housing 30. Here too, the conversion element 20 is again formed as a conversion layer. The potting 40 can be formed, for example, from a silicone or epoxy resin and has a transmittance for electromagnetic radiation of the semiconductor chip 10 that is at least 85%, preferably 95%.

The components shown in FIGS. 1 and 2 are LEDs, for example. For the sake of clarity, additional elements, such as electrical contacts, are not shown in FIGS. 1 and 2.

As the luminophore 1, a luminophor of the general formula A₄L₃₋ₓM₁₊ₓN₉₋ₓOₓ:RE, wherein 0≤x≤3,
A is an element or a combination of elements from the group of rare earth elements,
L is an element or a combination of elements from the group of tetravalent elements,
M is an element or a combination of elements from the group of trivalent elements, and
RE is an activator element can be used.

In the following, the luminophore 1 is explained in more detail with reference to exemplary embodiments 1 to 5 with the composition La₄Si₃₋ₓAl₁₊ₓN₉₋ₓOₓ:Ce. In exemplary embodiments 1 to 5, La is chosen as A, Si as L, Al as M and Ce as RE and x is variable.

To synthesize La₄Si₃₋ₓAl₁₊ₓN₉₋ₓOₓ:Ce, the reactants LaN, Si₃N₄, AlN, optionally Al₂O₃ und CeO₂ are mixed together. This can be done, for example, in a hand mortar, a mortar mill, a ball mill, a multi-axis mixer or similar. The resulting reactant mixture is then transferred to a crucible, which can be made of tungsten, for example. The reactant mixture is then heated under a forming gas atmosphere at 1700° C. and a pressure of 1 bar to 10 bar for 12 hours and thus brought to reaction. After reaction and cooling, the resulting product is ground, which can be done in a hand mortar, a mortar mill or a ball mill, for example. The luminophore 1 obtained in this way is then characterized.

The result is a dark reddish-brown powder that fluoresces blue-green or greenish-yellow to reddish under ultraviolet or blue light.

Table 1 shows the exemplary weights of the reactants for the individual exemplary embodiments 1 to 5.

TABLE 1

| Exemplary | | | | | |
|---|---|---|---|---|---|
| embodiment | x | CeO₂ | LaN | Si₃N₄ | AlN |
| 1 | 1.00 | 0.1 g | 8.6548 g | 0.5816 g | 0.6636 g |
| 2 | 2.20 | 0.02 g | 1.5468 g | 0.0961 g | 0.3370 g |
| 3 | 1.67 | 0.02 g | 1.3868 g | 0.2155 g | 0.3777 g |
| 4 | 0.60 | 0.02 g | 1.5285 g | 0.2850 g | 0.1665 g |
| 5 | 0.00 | 0.05 g | 3.8518 g | 0.8886 g | 0.2596 g |

Furthermore, Table 1 also lists values for the parameter x, which was determined from the nominal ratio of the elements Si and Al and represents a good initial estimate for the actual ratio of Si:Al.

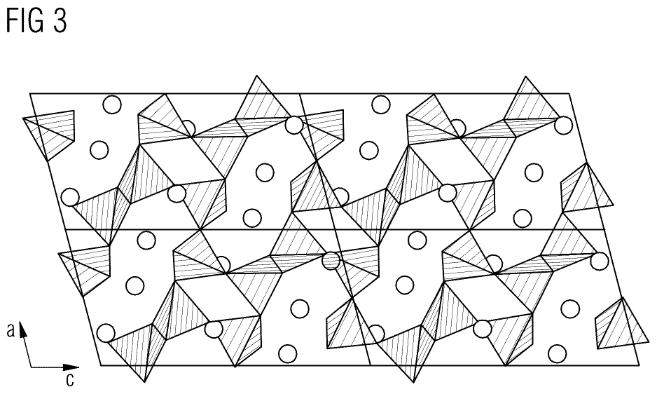

FIG. 3 shows a section of the crystal structure of the luminophore 1 with the composition La₄Si₃₋ₓAl₁₋ₓN₉₋ₓOₓ:Ce. The unfilled circles represent the La ions, the hatched areas represent the (N,O)₄-tetrahedra, which either surround Si, i.e. are Si-centered, or surround Al, i.e. are Al-centered.

The four-membered rings formed by the tetrahedra, which actually lie oblique in the plane, can be recognized.

In FIG. 3, no distinction is made between the tetrahedra of the first type and the tetrahedra of the second type. However, there are first Si(N,O)₄-tetrahedra and second Si(N,O)₄-tetrahedra as well as first Al(N,O)₄-tetrahedra and second Al(N,O)₄-tetrahedra, wherein the first and second tetrahedra differ crystallographically. The first Si(N,O)₄-tetrahedra and first Al(N,O)₄-tetrahedra are corner-linked on all sides to two further first Si(N,O)₄-tetrahedra and/or first Al(N,O)₄-tetrahedra and to two second Si(N,O)₄-tetrahedra and/or second Al(N,O)₄-tetrahedra. The second Si(N,O)₄-tetrahedra and second Al(N,O)₄-tetrahedra are linked via a total of three corners to two first Si(N,O)₄-tetrahedra and/or first Al(N,O)₄-tetrahedra and to one second Si(N,O)₄-tetrahedron or second Al(N,O)₄-tetrahedron.

The four-membered rings shown in FIG. 3 each contain two tetrahedra of the first type and two tetrahedra of the second type, wherein a tetrahedron of one type is only linked to two tetrahedra of the other type within the four-membered ring, i.e. there is an alternating sequence of the first and second tetrahedra within the four-membered ring (not explicitly shown). The four-membered rings are connected to other four-membered rings via corners of the tetrahedra. The connection to the next four-membered ring is made to a tetrahedron of the same type. The tetrahedra of the first type thus link to two further tetrahedra of the first type, which are each part of two further four-membered rings. The tetrahedra of the second type only link to one further tetrahedron of the second type, which is part of another four-membered ring. The fourth corner of the tetrahedra of the second type has a terminal anion (N or O).

In this way, a three-dimensional network of corner-linked tetrahedra is created. In this spatial network, cavities or channels are created in which the La ions (unfilled circles in FIG. 3) are arranged. The La ions are distributed over two crystallographic positions. This means that there are two symmetrically different positions in the structure on which La can be found. Both La positions are surrounded by seven anions, i.e. N and/or O. The anions form distorted, simply capped octahedra.

The structure of the luminophore 1 according to the exemplary embodiments is determined by single crystal X-ray diffraction. Table 2 shows the lattice parameters, crystallographic data and the basic quality parameters of the X-ray diffraction determination of exemplary embodiment 5. In addition to the lattice parameters a, b, c, α, β, and γ of the unit cell and the associated volume, the measured section of the reciprocal space over the limits of the associated Miller indices (hkl) is also given. Furthermore, the conventional R-value of all reflections Rₐ₁₁ is given, which indicates the mean percentage deviation between observed and calculated structure factors. The weighted R-value wR_{ref} contains a weighting factor that weights the reflexes according to a defined scheme depending on their standard deviation, among other things. For a good structural model, Rₐ₁₁ should be below 5% and wR_{ref} below 10%. The goodness of fit (GooF), which should be close to 1, is specified as a further quality feature for the agreement between the calculated and measured structure.

TABLE 2

| | |
|---|---|
| Total formula | La₄Si₃AlN₉:Ce³⁺⁺ |
| Formula mass/g mol⁻¹ | 792.92 |
| Z | 6 |
| Crystal system | Monoclinic |
| Space group | P2₁/n |

Grid parameters

| | | | |
|---|---|---|---|
| a/pm | 673.37(2) | α/° | 90 |
| b/pm | 557.18(2) | β/° | 104.5600(10) |
| c/pm | 1288.30(4) | γ/° | 90 |

| | |
|---|---|
| Volume V/nm³ | 0.46783 (3) |
| Crystallographic density ρ/g | 5.629 |
| cm⁻³ | |
| T/K | 296 (2) |
| Diffractometer | Bruker D8 Quest |
| Radiation | Cu K_{α} (154.178 nm) |
| Measurement range | 6.8286° ≤ θ ≤ 74.5541° |
| Measured/independent | 15960/944 |
| reflexes | |
| Measured reciprocal space | −7 ≤ h ≤ 8; |
| | −6 ≤ k ≤ 6; |
| | −16 ≤ l ≤ 16 |
| Rₐₗₗ/wR_{ref} | 2.33%/5.78% |
| GooF | 1.108 |

The crystallographic position parameters of exemplary embodiment 5 that were further determined are summarized in Table 3. The Wyckoff position describes the symmetry of the point positions according to R. W. G. Wyckoff. x, y and z indicate the atomic positions. Uₐₙᵢ is the radius of the anisotropic deflection parameter of the respective atom.

TABLE 3

| | Atom | Wyckoff- | | | | | | | | | |
|---|---|---|---|---|---|---|---|---|---|---|---|
| Name | type | position | x | | y | | z | | Occupancy | Uₐₙᵢ | |
| La1 | La | 4e | 0.91539 | (5) | 1.28720 | (6) | 0.29524 | (3) | 1 | 0.00954 | (13) |
| La2 | La | 4e | 0.73752 | (6) | 1.19694 | (6) | 0.55066 | (3) | 1 | 0.01380 | (14) |
| Si3 | Si | 4e | 0.7833 | (2) | 0.6765 | (3) | 0.44791 | (13) | 0.5 | 0.0063 | (3) |
| Al3 | Al | 4e | 0.7833 | (2) | 0.6765 | (3) | 0.44791 | (13) | 0.5 | 0.0063 | (3) |
| Si4 | Si | 4e | 0.3758 | (3) | 0.3366 | (3) | 0.32241 | (13) | 1 | 0.0121 | (3) |
| N5 | N | 2d | 1 | | 0.5 | | 0.5 | | 1 | 0.0158 | (16) |
| N6 | N | 4e | 0.6267 | (8) | 0.4768 | (9) | 0.3583 | (4) | 1 | 0.0138 | (11) |
| N7 | N | 4e | 0.6771 | (8) | 0.7584 | (10) | 0.5510 | (4) | 1 | 0.0132 | (11) |
| N8 | N | 4e | 0.8446 | (8) | 0.9216 | (9) | 0.3819 | (4) | 1 | 0.0125 | (10) |
| N9 | N | 4e | 0.3127 | (8) | 0.0758 | (10) | 0.2357 | (4) | 1 | 0.0167 | (11) |

The crystallographic position parameters in Table 3 can be used to differentiate between the first and second tetrahedra. While Si4 can be assigned to the first Si(N,O)₄-tetrahedra, Si3 and Al3 belong to the second Si(N,O)₄-tetrahedra and Al(N,O)₄-tetrahedra respectively.

Table 4 summarizes the spectral data with peak wavelength, dominant wavelength and half-width FWHM determined for exemplary embodiments 1 to 5. The spectral data were obtained under combined excitation with a combination of monochromatic radiation of 405 nm and 440 nm in each case.

TABLE 4

| Exemplary | | | | |
|---|---|---|---|---|
| embodiment | Peak wavelength | Dominant wavelength | FWHM | |
| 1 | 492 nm | 515 nm | >76 | nm |
| 2 | 515 nm | 553 nm | >122 | nm |
| 3 | 588 nm | 575 nm | 148 | nm |
| 4 | 598 nm | 582 nm | 116 | nm |
| 5 | 619 nm | 585 nm | ≥131 | nm |

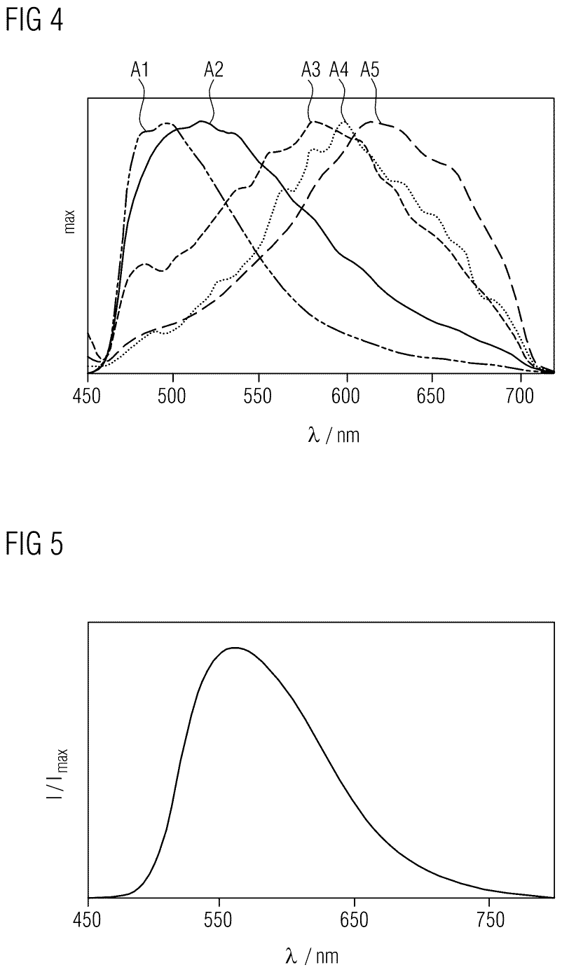

The corresponding emission spectra of exemplary embodiments 1 to 5 (labeled A1 to A5) are shown in FIG. 4. The wavelength λ in nm is plotted against the relative intensity I/Iₘₐₓ.

FIG. 5 shows the emission spectrum of the comparative example YAG. YAG is Y₃Al₅O₁₂:Ce, one of the most long-wave Ce³⁺-activated luminophores in use today, with which dominant wavelengths of 555 nm to 574 nm can be realized.

When comparing the spectral data and associated emission spectra of the exemplary embodiments and the comparative example YAG, it is clearly recognizable that the luminophore 1 described here has an adaptability of the emission color over a larger wavelength range than the comparative example YAG. This means that luminophore 1 can be used to realize an efficient and inexpensive solution for various applications without having to use different luminophor systems for different desired wavelength ranges.

Table 5 shows the color temperatures CCT and color rendering indices CRI for three application examples in the yellow-orange-red spectral range. In each of the application examples, an exemplary embodiment is used as the only luminophore in the conversion element 20 and a blue-emitting LED chip is used as the semiconductor chip 10. The numbering of the application examples corresponds to the numbering of the respective exemplary embodiments used.

TABLE 5

| | x | CCT [K] | CRI |
|---|---|---|---|
| Application example 3 | 1.67 | 4005 | 81 |
| Application example 4 | 0.60 | 3069 | 84 |
| Application example 5 | 0.00 | 1929 | 81 |

The CRI values of the application examples are in the range of CRI 81 to 84. In comparison to the comparative example YAG with a CRI of 63, the application examples of the luminophore described here achieve significantly better CRI values.

The achievable color temperature depends directly on the emission position. For the comparative example YAG, the simulated color temperature is 4369 K, which is one of the lowest color temperatures that can be achieved with conventional Ce³⁺-activated luminophores. Color temperatures CCT<4000 K are usually not achievable with these conventional luminophores.

The simulated color temperatures of application examples 1 to 3 of luminophore 1, on the other hand, reach values between 1929 K and 4005 K inclusive. This means that luminophore 1 considerably extends the range in which Ce³⁺-activated luminophores in particular can be used compared to the solutions available to date.

Application examples 3 to 5 are therefore well suited for applications where, in addition to brightness, a slight red component of the emitted radiation is also important, such as, for example, in general lighting, in car headlights or flash lights.

Exemplary embodiments 1 and 2 with dominant wavelengths of 515 nm and 553 nm are spectrally advantageous for Human Centric Lighting (HCL) applications. Due to their spectral position, they have a higher overlap with the melanopic curve than, for example, conventional LuAG (Lu₃Al₅O₁₂:Ce). With a suitable composition, luminophore 1 can therefore be used advantageously for HCL applications and its effect on, for example, the alertness of the observer can be exploited.

The features and exemplary embodiments described in connection with the figures can be combined with one another according to further exemplary embodiments, even if not all combinations are explicitly described. Furthermore, the exemplary embodiments described in connection with the figures may alternatively or additionally have further features as described in the general part.

The invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

### LIST OF REFERENCE SYMBOLS

1 Luminophore
10 Semiconductor chip
11 Radiation exit surface
12 Active zone
20 Conversion element
30 Housing
40 Potting
100 Radiation-emitting component
λ Wavelength
I/Iₘₐₓ Intensity
A1 Exemplary embodiment 1
A2 Exemplary embodiment 2
A3 Exemplary embodiment 3
A4 Exemplary embodiment 4
A5 Exemplary embodiment 5

1. A luminophore with the general formula 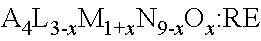
where 0≤x≤3,
A is an element or a combination of elements from the group of rare earth elements,
L is an element or a combination of elements from the group of tetravalent elements,
M is an element or a combination of elements from the group of trivalent elements, and
RE is an activator element.

2. The luminophore according to claim 1, wherein RE is an element or a combination of elements from the group Ce, Eu, Tb, Sm and Pr.

3. The luminophore according to claim 1, wherein L is Si.

4. The luminophore according to claim 1, wherein M is Al.

5. The luminophore according to claim 1, which has the general formula La₄Si₃₋ₓAl₁₊ₓN₉₋ₓOₓ:RE with 0<x≤3.

6. The luminophore according to claim 1, wherein the luminophore has the general formula La₄Si₃₋ₓAl₁₊ₓN₉₋ₓOₓ:Ce.

7. The luminophore according to claim 1, wherein the luminophore crystallizes in a monoclinic space group.

8. The luminophore according to claim 1, wherein the luminophore comprises first L-centered L(N,O)₄-tetrahedra, first M-centered M(N,O)₄-tetrahedra, second L-centered L(N,O)₄-tetrahedra and second M-centered M(N,O)₄-tetrahedra, wherein the first L-centered L(N,O)₄-tetrahedra and M-centered M(N,O)₄-tetrahedra are corner-linked on all sides and the second L-centered L(N,O)₄-tetrahedra and M-centered M(N,O)₄-tetrahedra each have a terminal N or O.

9. The luminophore according to claim 8, wherein
the first L-centered L(N,O)₄-tetrahedra and M-centered M(N,O)₄-tetrahedra are linked to two first L-centered L(N,O)₄-tetrahedra and/or M-centered M(N,O)₄-tetrahedra and to two second L-centered L(N,O)₄-tetrahedra and/or M-centered M(N,O)₄-tetrahedra, and
wherein
the second L-centered L(N,O)₄-tetrahedra and M-centered M(N,O)₄-tetrahedra are linked to two first L-centered L(N,O)₄-tetrahedra and/or M-centered M(N,O)₄-tetrahedra and to one second L-centered L(N,O)₄-tetrahedron or M-centered M(N,O)₄-tetrahedron.

10. The luminophore according to claim 8, wherein the first L-centered L(N,O)₄-tetrahedra, first M-centered M(N,O)₄-tetrahedra, second L-centered L(N,O)₄-tetrahedra and second M-centered M(N,O)₄-tetrahedra form four-membered rings.

11. The luminophore according to claim 1, wherein the luminophore has an absorption range at least in the UV to blue wavelength range of the electromagnetic spectrum.

12. The luminophore according to claim 1, wherein the luminophore emits in the blue-green to red wavelength range of the electromagnetic spectrum.

13. The luminophore according to claim 1, wherein an electromagnetic radiation emitted from the luminophore has a dominant wavelength between 500 nm and 600 nm inclusive.

14. The luminophore according to claim 1, wherein an electromagnetic radiation emitted by the luminophore has an emission maximum of at least one emission peak between 480 nm and 630 nm inclusive.

15. The luminophore according to claim 1, wherein an electromagnetic radiation emitted by the luminophore has a spectral half-width between 70 nm and 160 nm inclusive.

16. A method for producing a luminophore having the general formula 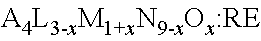
where 0≤x≤3,
A is an element or a combination of elements from the group of rare earth elements,
L is an element or a combination of elements from the group of tetravalent elements,
M is an element or a combination of elements from the group of trivalent elements, and
RE is an activator element,
comprising the steps
provision of reactants,
mixing the reactants to form a mixture of reactants, and
heating the reactant mixture.

17. The method according to claim 16, wherein the reactant mixture is heated to a temperature in the range from 1500° C. to 1900° C. inclusive and/or
whereby the reactant mixture is heated for a period of 10 hours up to and including 14 hours.

18. The method according to claim 16, wherein the reactant mixture is heated under a forming gas atmosphere or N₂ atmosphere, and/or wherein the reactant mixture is heated under a pressure of up to 12 bar.

19. A radiation-emitting component comprising:
a semiconductor chip which emits electromagnetic radiation of a first wavelength range during operation, and
a conversion element comprising a luminophore according to claim 1, which converts electromagnetic radiation of the first wavelength range into electromagnetic radiation of a second wavelength range which is at least partially different from the first wavelength range.

20. The radiation-emitting component according to claim 19, wherein the conversion element is free of a further luminophore.
